(19) United States
(12) Patent Application Publication
(10) Pub. No.: US 2024/0232458 A1
(43) Pub. Date: Jul. 11, 2024

(54) METHOD AND SYSTEM FOR ANALYSING SIMULATION DATA USING SIGNATURES

(71) Applicant: HCL America Inc., Sunnyvale, CA (US)

(72) Inventors: MANICKAM MUTHIAH, Shrewsbury, MA (US); KARTHIKEYAN KEELAPANDAL SUNDARAM, Chennai (IN); NISHA RAVICHANDRAN, Hudson, MA (US); RAZI ABDUL RAHIM, Willowbrook, IL (US)

(21) Appl. No.: 18/095,635

(22) Filed: Jan. 11, 2023

(51) Int. Cl. G06F 30/20

(52) U.S. Cl. CPC G06F 30/20

(57) ABSTRACT

A method for analysing simulation data is disclosed. In some embodiments, the method includes creating a set of data extract files from simulation logs associated with a current simulation run. The method further includes generating a unique signature for each of the set of data extract files. The method further includes creating a signature log file comprising the unique signature generated for each of the set of data extract files. The method further includes generating a consolidated signature for the signature log file. The method further includes comparing the consolidated signature with a prior consolidated signature generated for a prior simulation run. The method further includes determining whether the current simulation run deviates from the prior simulation run, based on the comparison between the consolidated signature and the prior consolidated signature.

### TECHNICAL FIELD

Generally, the invention relates to functional simulation. More specifically, the invention relates to method and system for analyzing simulation data using signatures.

### BACKGROUND

Once a device or a system is manufactured, before it is sold or put to actual use, it is tested in a test environment to verify functional correctness or soundness. The verification of the device or system is done to make sure that the device or system is fit for usage before it is used in markets. As opposed to a conventional analytical approach used to investigate the device for its functional correctness, which was purely theoretical, the analysis of the device via a simulation technique is more reliable as it is more flexible and convenient. Further, in order to test and analyze the device via the simulation technique, results of one simulation run may be compared with corresponding results obtained for another simulation run.

In the test environment, during the verification of the functional correctness of a Device Under Test (DUT) ((or a System Under Test (SUT)), a deviation might occur in simulation results between a current simulation run and a prior simulation run. The deviation in the current simulation run may depict a failure or variance in the current simulation run when compared to the prior simulation run that executed with or without any error. Currently, in order to compare simulation data of the current simulation run with the simulation data of the prior passing or failing simulation run to identify a reason for a failure or variance, a user (e.g. a developer or a tester) has to manually compare the simulation data associated with the current simulation run and the prior simulation run. This process of manual comparison of the simulation data may be tedious and time consuming, as the amount of log data that needs to be reviewed might be huge given the volume of the logs generated.

Further, in order to understand the reason of failure of simulation run, some conventional applications can be used to generate precise results. However, the user cannot completely rely on the results obtained via these applications, as these applications are pre-programmed with the established results and any change in the test environment may generate false positive results. Further, these conventional applications need to be updated and reprogrammed to keep up with the changes, which again is a time-consuming process.

Therefore, there is a need of implementing an efficient and reliable technique for analyzing the simulation data to automatically identify deviations.

### SUMMARY OF INVENTION

In one embodiment, a method for analyzing simulation data is disclosed. The method may include creating a set of data extract files from simulation logs associated with a current simulation run. The method may include generating a unique signature for each of the set of data extract files. The method may include creating a signature log file comprising the unique signature generated for each of the set of data extract files. The method may include generating a consolidated signature for the signature log file. The method may include comparing the consolidated signature with a prior consolidated signature generated for a prior simulation run. The method may include determining whether the current simulation run deviates from the prior simulation run, based on the comparison between the consolidated signature and the prior consolidated signature.

In another embodiment, a system for analyzing simulation data is disclosed. The system includes a processor and a memory communicatively coupled to the processor. The memory may store processor-executable instructions, which, on execution, may cause the processor to create a set of data extract files from simulation logs associated with a current simulation run. The processor-executable instructions, on execution, may further cause the processor to generate a unique signature for each of the set of data extract files. The processor-executable instructions, on execution, may further cause the processor to create a signature log file comprising the unique signature generated for each of the set of data extract files. The processor-executable instructions, on execution, may further cause the processor to generate a consolidated signature for the signature log file. The processor-executable instructions, on execution, may further cause the processor to compare the consolidated signature with a prior consolidated signature generated for a prior simulation run. The processor-executable instructions, on execution, may further cause the processor to determine whether the current simulation run deviates from the prior simulation run, based on the comparison between the consolidated signature and the prior consolidated signature.

In yet another embodiment, a non-transitory computer-readable medium storing computer-executable instruction for analysing simulation data is disclosed. The stored instructions, when executed by a processor, may cause the processor to perform operations including creating a set of data extract files from simulation logs associated with a current simulation run. The operations may further include generating a unique signature for each of the set of data extract files. The operations may further include creating a signature log file comprising the unique signature generated for each of the set of data extract files. The operations may further include generating a consolidated signature for the signature log file. The operations may further include comparing the consolidated signature with a prior consolidated signature generated for a prior simulation run. The operations may further include determining whether the current simulation run deviates from the prior simulation run, based on the comparison between the consolidated signature and the prior consolidated signature.

It is to be understood that both the foregoing general description and the following detailed description are exemplary and explanatory only and are not restrictive of the invention, as claimed.

### BRIEF DESCRIPTION OF THE DRAWINGS

The present application can be best understood by reference to the following description taken in conjunction with the accompanying drawing figures, in which like parts may be referred to by like numerals.

FIG. 1 illustrates an environment diagram representing a simulation test environment of a Device Under Test (DUT), in accordance with an exemplary embodiment.

FIG. 2 illustrates a functional diagram of a system configured for analyzing simulation data for a functional simulation, in accordance with an embodiment.

FIG. 3 illustrates a flowchart of a method for analyzing simulation data, in accordance with an embodiment.

FIG. 4 illustrates a flowchart of a method for creating a set of data extract files, in accordance with an embodiment.

FIG. 5 illustrates a flowchart of a method for generating a unique signature for a data extract file, in accordance with an embodiment.

FIG. 6 illustrates a flowchart of a method for creating a signature log file, in accordance with an embodiment.

FIG. 7 illustrates a flowchart of a method for creating a signature log file, in accordance with an embodiment.

FIG. 8 represents a snapshot of a signature log file, in accordance with an exemplary embodiment.

FIG. 9 illustrates a flowchart of a method for generating a consolidated signature for a signature log file, in accordance with an embodiment.

FIG. 10 represents a snapshot of a consolidated signature, in accordance with an exemplary embodiment.

FIG. 11 illustrates a flowchart of a method for comparing a consolidated signature with a prior consolidated signature, in accordance with an embodiment.

FIG. 12 represents a snapshot of comparison of a consolidated signature of a current simulation run with a consolidated signature of a prior simulation run, in accordance with an exemplary embodiment.

FIG. 13 illustrates a flowchart of a method for comparing a unique signature generated for each of a set of data extract files with a prior unique signature generated for a corresponding prior data extract file of a prior simulation run, in accordance with an embodiment.

FIG. 14 represents a snapshot of comparison of a unique signature of generated for each of a set of data extract files with a prior unique signature generated for a corresponding prior data extract file of a prior simulation run, in accordance with an exemplary embodiment.

FIG. 15 illustrates a flowchart of a method for identifying at least one data extract file with deviations from a set of data extract files, in accordance with an exemplary embodiment.

### DETAILED DESCRIPTION OF THE DRAWINGS

The following description is presented to enable a person of ordinary skill in the art to make and use the invention and is provided in the context of particular applications and their requirements. Various modifications to the embodiments will be readily apparent to those skilled in the art, and the generic principles defined herein may be applied to other embodiments and applications without departing from the spirit and scope of the invention. Moreover, in the following description, numerous details are set forth for the purpose of explanation. However, one of ordinary skill in the art will realize that the invention might be practiced without the use of these specific details. In other instances, well-known structures and devices are shown in block diagram form in order not to obscure the description of the invention with unnecessary detail. Thus, the invention is not intended to be limited to the embodiments shown, but is to be accorded the widest scope consistent with the principles and features disclosed herein.

While the invention is described in terms of particular examples and illustrative figures, those of ordinary skill in the art will recognize that the invention is not limited to the examples or figures described. Those skilled in the art will recognize that the operations of the various embodiments may be implemented using hardware, software, firmware, or combinations thereof, as appropriate. For example, some processes can be carried out using processors or other digital circuitry under the control of software, firmware, or hard-wired logic. (The term “logic” herein refers to fixed hardware, programmable logic and/or an appropriate combination thereof, as would be recognized by one skilled in the art to carry out the recited functions.) Software and firmware can be stored on computer-readable storage media. Some other processes can be implemented using analog circuitry, as is well known to one of ordinary skill in the art. Additionally, memory or other storage, as well as communication components, may be employed in embodiments of the invention.

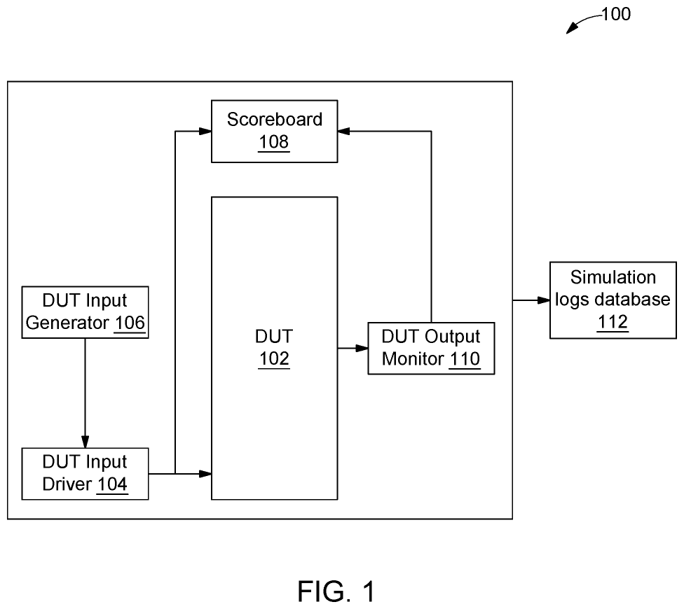

Referring now to FIG. 1, an environment 100 representing a simulation test environment of a Device Under Test 102 is illustrated, in accordance with an exemplary embodiment. As depicted via FIG. 1, the simulation test environment for the DUT 102 to be tested may include a DUT input driver 104, a DUT input generator 106, a scoreboard 108, and a DUT output monitor 110. In order to test the DUT 102 for functional correctness, the DUT input generator 106 may be configured to generate an input stimulus corresponding to the DUT 102. The input stimulus generated may be received by the DUT 102 via the DUT input driver 104. Additionally, the scoreboard 108 may be simultaneously updated with the input stimulus provided to the DUT 102.

Upon receiving the input stimulus, the DUT 102 may be tested corresponding to the received input stimulus. Further an output of the DUT 102 may be provided to the DUT output monitor 110. In addition, the scoreboard 108 may be consecutively updated based on the output obtained corresponding to the input stimulus received by the DUT 102. As will be appreciated, the environment 100 depicted via the present FIG. 1 is one example and is not limiting to the scope of the invention. In addition, in order to test any DUT, the simulation test environment may include a plurality of testbench components as per requirement of the DUT. The plurality of testbench components present in the simulation test environment may include, but is not limited to, an agent, sequencer, a driver, a monitor, a scoreboard, a checker, and a coverage collector.

Further, based on the testing performed for the DUT 102, simulation transcript, results of testing along with corresponding information associated with each testbench component may be stored as simulation logs or log files in a simulation logs database 112. The simulation logs database 112 may be iteratively updated with simulation logs or log files corresponding to the simulation run, input stimulus and different testbench components. In an embodiment, the simulation logs database 112 may be accessed by the user as per requirement. The user may access the simulation logs database 112 for performing simulation data analysis for multiple simulation runs performed for verifying functionality of the DUT 102.

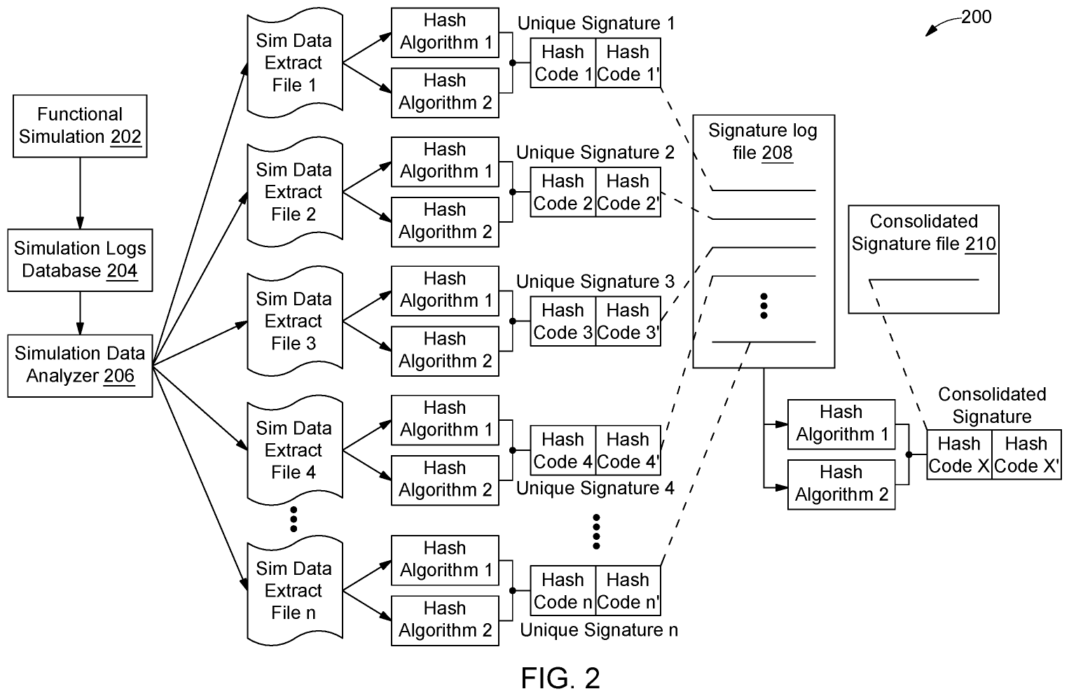

Referring now to FIG. 2, a functional diagram of a system 200 configured for analyzing simulation data for a functional simulation 202 is illustrated, in accordance with an embodiment. In order to analyze the simulation data corresponding to the functional simulation 202, the system 200 may include a simulation data analyzer 206. In FIG. 2, the functional simulation 202 may correspond to a single simulation run (i.e., a current simulation run) performed in the test environment to verify the functionality of a DUT (same as the DUT 102).

In order to analyze the simulation data corresponding to the functional simulation 202, the simulation data analyzer 206 may access the simulation logs present in the simulation logs database 204. With reference to FIG. 1, the simulation logs database 204 may correspond to the simulation log database 112. In an embodiment, the simulation data analyzer 206 may correspond to a tool that is configured to generate a consolidated signature file 210 to determine whether the current simulation run deviates from a prior simulation run.

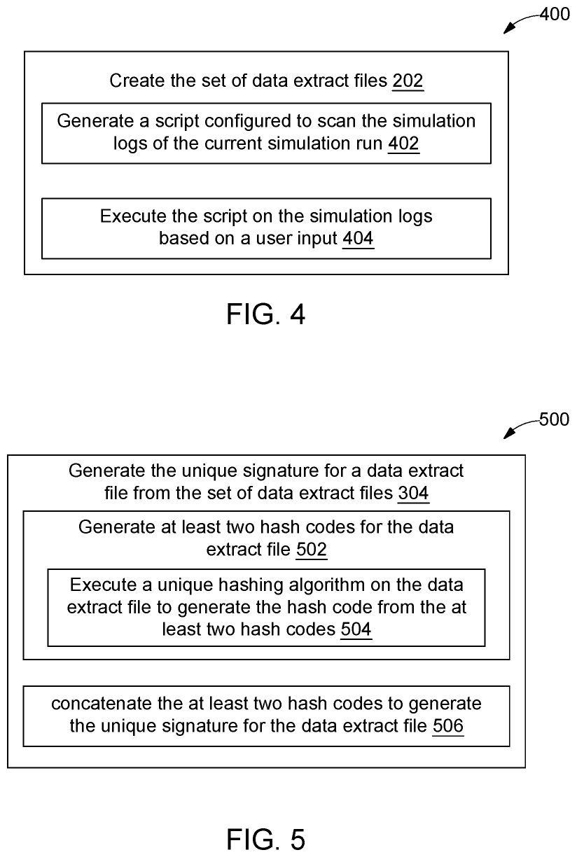

In order to analyze the simulation data corresponding to the functional simulation 202, the simulation data analyzer 206 may create a set of data extract files corresponding to the functional simulation 202. In order to create the set of data extract files, initially, the simulation data analyzer 206 may be configured to analyze the simulation logs corresponding to the functional simulation 202 present in the simulation logs database 204. By way of an example, the simulation logs may include, but are not limited to, a simulation transcript log, a driver log, a monitor log, a checker log, and a scoreboard log. Based on analysis of the simulation logs stored in the simulation logs database 204, the set of data extract files may be created. Examples of the set of data extract files may include, but are not limited to, Device Under Test (DUT) or Register Transfer Level (RTL) and Testbench (TB) configurations, a list of checker checks, a list of scoreboard checks, a summary report of checks, a start simulation time, an end simulation time, an input stimulus window, a list of error messages, and a list of warning messages. As will be appreciated, the user may create the set of data extract files based on his requirements. A method of creating the set of data extract files has been explained in detail in conjunction with FIG. 4.

As depicted FIG. 2, the set of data extract files created by the simulation data analyzer 206 may correspond to a sim data extract file 1, a sim data extract file 2, a sim data extract file 3, a sim data extract file 4, up to a sim data extract file ‘n’. It should be noted that, the simulation data analyzer 206 may create any number of data extract files based on project and user requirements.

Once the set of data extract files are created, the simulation data analyzer 206 may generate a unique signature for each of the set of data extract files. The unique signature for each of the set of data extract files may be generated by concatenating two hash codes generated for each of the set of data extract files. In an embodiment, each of the two hash codes may be generated by executing two different hashing algorithms on each data extract file. As depicted via FIG. 2, in order to generate a unique signature 1 for the sim data extract file 1, two hashing algorithms, i.e., a hash algorithm 1 and a hash algorithm 2 may be individually executed on the sim data extract file 1 to generate the two hash codes, i.e., a hash code 1 and a hash code 1′. By way of an example, the two hashing algorithms, i.e., the hash algorithm 1 and the hash algorithm 2 may correspond to a sha512sum and a sha256sum, respectively. Other examples of hashing algorithms may include, but are not limited to, MD5, SHA-1, SHA-2, NTLM, and LANMAN. It should be noted that, each of the two hash codes, i.e., the hash code 1 and the hash code 1′, generated for the sim data extract file 1 would be unique.

Upon generating the hash code 1 and the hash code 1′, the hash code 1 and the hash code 1′ may be concatenated to generate the unique signature 1 for the sim data extract file 1. In a similar manner, the unique signature may be generated for each of the set of data extract files. In an embodiment, the unique signature generated for the sim data extract file 1, the sim data extract file 2, the sim data extract file 3, the sim data extract file 4, up to the sim data extract file ‘n’ may correspond to a unique signature 1, a unique signature 2, a unique signature 3, a unique signature 4, up to a unique signature ‘n’, respectively. It should be noted that, the two different hashing algorithms, i.e., the hash algorithm 1 and the hash algorithm 2 used for generating the unique signature 1 for the sim data extract file 1 may be the same for other data extract files as depicted in the present FIG. 2. Further, in some embodiment, the unique signature corresponding to each of the set of data extract files may be generated by using more than two hashing algorithms.

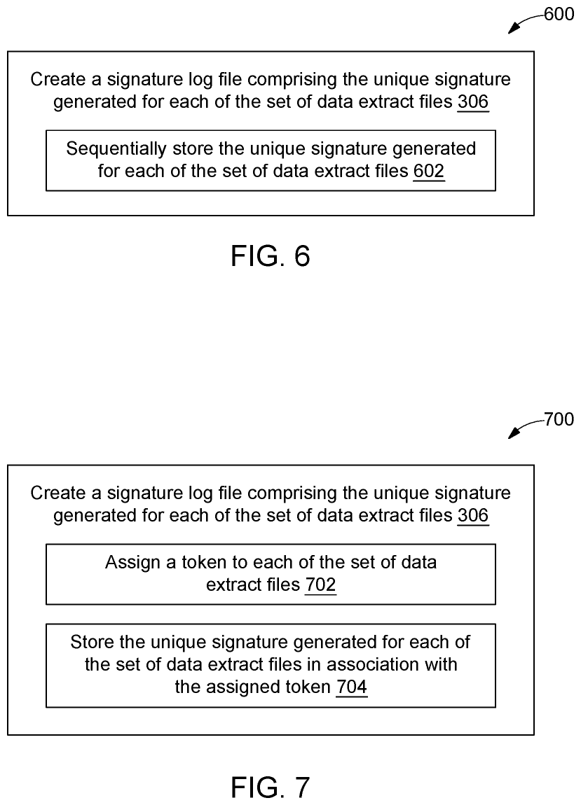

Once the unique signature corresponding to each of the set of data extract files are generated, the simulation data analyzer 206 may create a signature log file. The signature log file may store the unique signature created for each of the set of data extract files. As represented via FIG. 2, the signature log file created for the sim data extract file 1, the sim data extract file 2, the sim data extract file 3, the sim data extract file 4, up to the sim data extract file ‘n’ may correspond to a signature log file 208. A method of creating the signature log file is further explained in detail in conjunction with FIG. 6 and FIG. 7. The signature log file 208 may store the unique signature 1, the unique signature 2, the unique signature 3, the unique signature 4, up to the unique signature ‘n’.

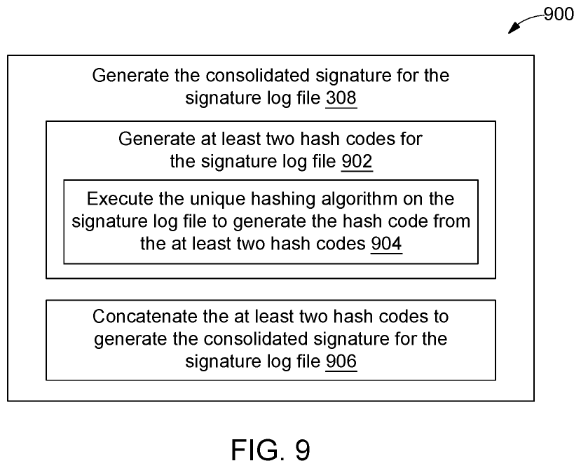

Once the signature log file 208 is created, the simulation data analyzer 206 may be configured to generate a consolidated signature for the signature log file 208. In order to generate the consolidated signature, initially, the two hashing algorithms, i.e., hash algorithm 1 (e.g., sha512sum) and the hash algorithm 2 (e.g., sha256sum) may be executed on the signature log file 208 to generate a hash code X and a hash code X′ for the signature log file 208. Once the hash code X and the hash code X′ are generated, then the hash code X and the hash code X′ may be concatenated to generate the consolidated signature for the signature log file 208. A method of generating the consolidated signature is further explained in detail in conjunction with FIG. 9. Further, the generated consolidated signature may be stored in a consolidated signature file 210. As will be appreciated, the consolidated signature may be generated for any number of simulations runs with the same test environment using the technique described above in current FIG. 2.

Once the consolidated signature is generated for the current simulation run (i.e., the functional simulation 202), the simulation data analyzer 206 may compare the consolidated signature generated for the current simulation run with a prior consolidated signature generated for a prior simulation run. In one embodiment, the prior simulation run may correspond to a simulation run executed without any issue, i.e., a golden simulation run. In another embodiment, the prior simulation run may correspond to a simulation run that executed with at least one issue. Further, based on the comparison between the consolidated signature and the prior consolidated signature, the simulation data analyzer 206 may identify whether the current simulation run deviates from the prior simulation run. In one embodiment, based on comparison between the consolidated signature and the prior consolidated signature, the current simulation may be identified as identical to the prior simulation run. In another embodiment, based on comparison between the consolidated signature and the prior consolidated signature, the current simulation may be identified as deviating from the prior simulation run.

By way of an example, in one embodiment, in first case, when the prior simulation run corresponds to the golden simulation run, then upon identifying the current simulation run being identical to the golden simulation run, the current simulation run may be determined to be a passing simulation run. Further, in second case, when the prior simulation run corresponds to the golden simulation run, and the current simulation run is identified as not identical to the golden simulation run, then a deviation may be identified in the current simulation run. In this case, the current simulation may correspond to a failing simulation run.

By way of another example, in second embodiment, in first case, when the prior simulation run corresponds to the simulation run that executed with at least one issue, and the current simulation run is identified to be identical as the prior simulation run, then the current simulation may include the at least one issue identified in the prior simulation run. Further, in second case, when the prior simulation run corresponds to the simulation run that executed with at least one issue, and the current simulation run is identified as not identical as the prior simulation run, then the consolidated signature for the current simulation may be compared with any other prior consolidated signature associated with a prior simulation run using the same test environment based on user requirement.

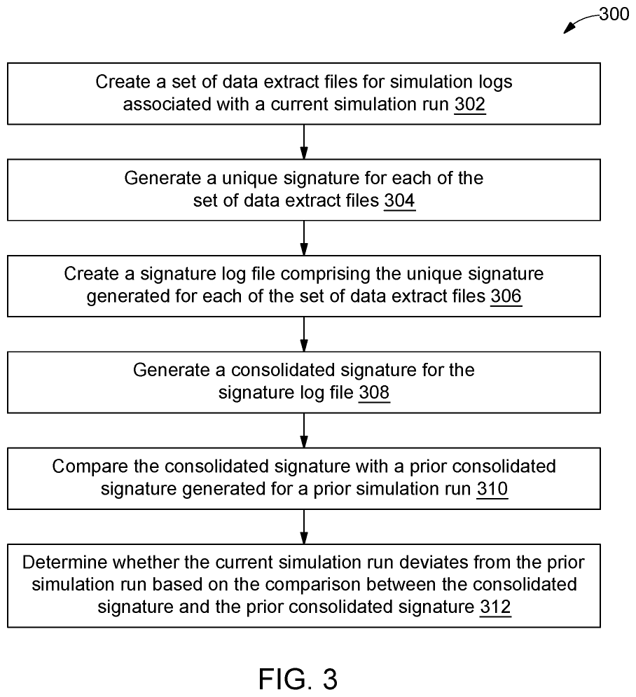

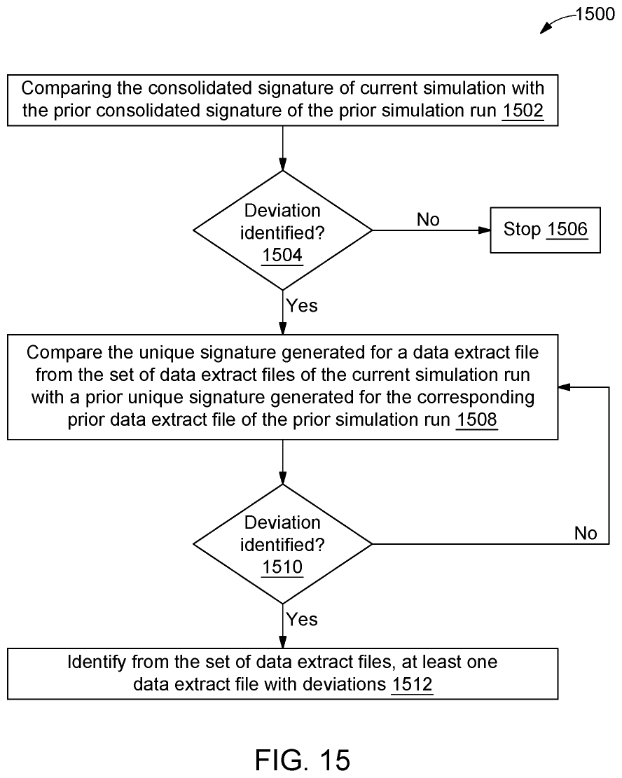

Upon identifying the deviation in the consolidated signature of the current simulation run from the prior consolidated signature, the set of data extract files associated with the current simulation run may be compared with corresponding prior data extract files of the prior simulation run. The comparison of the set of data extract files associated with the current simulation run with corresponding prior data extract files may include comparison of the unique signature generated for each of the set of data extract files with the prior unique signature generated for the corresponding prior data extract file of the prior simulation run. This is done to identify at least one data extract file from the set of data extract files associated with the current simulation run that has deviation from the prior simulation run. Upon identifying the at least one data extract file with deviation, the simulation data analyzer 206 may render salient data points (i.e., a simulation data) associated with the at least one data extract file to the user. The salient data points may depict an issue in the at least one data extract file associated with the current simulation run by comparing with the corresponding prior data extract file associated with the prior simulation run. A method of identifying the at least one data extract file with deviation from the set of data extract files is further explained in conjunction with FIG. 15. In addition, this complete method described in FIG. 2 is further explained in detail in conjunction with FIG. 3 to FIG. 15.

Referring now to FIG. 3, a flowchart of a method 300 for analyzing simulation data is illustrated, in accordance with an embodiment. In order to analyze the simulation data, initially, at step 302, a set of data extract files may be created from simulation logs or log files associated with a current simulation run. With reference to FIG. 2, the set of data extract files may correspond to the sim data extract file 1, the sim data extract file 2, the sim data extract file 3, the sim data extract file 4, up to the sim data extract file ‘n. In addition, the simulation logs or log files associated with the current simulation run (i.e., the functional simulation 202) may be stored in the simulation logs database 204. Examples of the simulation logs or log files may include, but is not limited to, a simulation transcript log, a driver log, a monitor log, a checker log, and a scoreboard log. Further, examples of the set of data extract files may include, but is not limited to, Device Under Test (DUT) or Register Transfer Level (RTL) and Testbench (TB) configurations, a list of checker checks, a list of scoreboard checks, a summary report of checks, a start simulation time, an end simulation time, an input stimulus window, a list of error messages, and a list of warning messages. As will be appreciated, a user may create any number of data extract files for the simulation logs based on his requirement. It should be noted that, each of the set of data extract files may include data from multiple simulation logs or log files or a single simulation log or log file present within the simulation logs database 204. The each of the set of data extract files may be created based on an input received from the user. A method of creating the set of data extract files is further explained in detail in conjunction with FIG. 4.

Once the set of data extract files are created, at step 304, a unique signature may be generated for each of the set of data extract files. In an embodiment, the unique signature for each of the set of data extract files may be generated by concatenating at least two hash codes (also referred as hash values) generated for each of the set of data extract files. In order to generate the at least two hash codes for each of the set of data extract files, two unique hashing algorithms may be individually executed on each of the set of data extract files.

With reference to FIG. 2, the two unique hashing algorithms may correspond to the hash algorithm 1 (e.g., the sha512sum) and the hash algorithm 2 (e.g., the sha 256sum). Examples of hashing algorithms that may be used to generate the at least two hash codes may include, but is not limited to, MD5, SHA-1, SHA-2, NTLM, and LANMAN. Further, the unique signature generated for the sim data extract file 1, the sim data extract file 2, the sim data extract file 3, the sim data extract file 4, up to the sim data extract file ‘n’ may correspond to a unique signature1, a unique signature2, a unique signature3, a unique signature4, up to a unique signature ‘n’, respectively. A method of generating the unique signature for each of the set of data extract files is further explained in detail in conjunction with FIG. 5.

Upon generating the unique signature, at step 306, a signature log file may be created. The signature log file may include the unique signature generated for each of the set of data extract files. In an embodiment, the signature log file may store the unique signature associated with each of the set of data extract files in a predefined sequence. The pre-defined sequence may include one of a sequence of creation of each of the set of data extract files or a token assigned to each of the set of data extract files. With reference to FIG. 2, the signature log file may correspond to the signature log file 208. A method of creating the signature log file is further explained in detail in reference to FIG. 6 and FIG. 7.

Once the signature log file is created, at step 308, a consolidated signature may be generated for the signature log file. In an embodiment, the consolidated signature may be generated by executing the two unique hashing algorithms, i.e., the hash algorithm 1 (e.g., the sha512sum) and the hash algorithm 2 (e.g., the sha 256sum) on the signature log file. A method of generating the consolidated signature is further explained in detail in reference to FIG. 9. With reference to FIG. 2, the generated consolidated signature may be stored in the consolidated signature file 210 for future reference. Further, at step 310, the generated consolidated signature may be compared with a prior consolidated signature generated for a prior simulation run. In one embodiment, the prior simulation run may correspond to a simulation run executed without any issue, i.e., a golden simulation run. In another embodiment, the prior simulation run may correspond to a simulation run that executed with at least one issue. As will be appreciated, different exemplary scenarios of comparison of the consolidated signature of the current simulation run with the prior consolidated signature of the prior simulation run has been already explained in FIG. 2.

Further, based on the comparison between the consolidated signature and the prior consolidated signature, at step 312, a deviation of the current simulation run from the prior simulation run may be determined. By way of an example, the user may be interested in viewing result of comparison of the consolidated signature of the current simulation with the prior consolidated signature of the golden simulation run. Upon receiving the user input for the comparison, the consolidated signature of the current simulation may be compared with the prior consolidated signature of the golden simulation run. With reference to FIG. 2, the simulation data analyzer 206 may receive the user input to compare the consolidated signature with the prior consolidated signature. Based on the comparison a result may be rendered to the user depicting whether the current simulation run deviates from the golden simulation run.

In one embodiment, based on the comparison, when the consolidated signature of the current simulation is identical to the prior consolidated signature of the golden simulation run, it may be determined that the current simulation run is a passing simulation run. However, when the consolidated signature of the current simulation is not identical to the prior consolidated signature of the golden simulation run, it may be determined that the current simulation run is a failed simulation run. Further, when the current simulation run may be determined to be the failing simulation run, the at least one data extract file with deviation may be identified from the set of data extract files. The set of data extract files may be associated with the current simulation run. A method of identifying the at least one data extract file with deviation from the set of data extract files is further explained in detail in conjunction with FIG. 15.

Referring now to FIG. 4, a flowchart of a method 400 for creating a set of data extract files is illustrated, in accordance with an embodiment. With reference to FIG. 3, in order to create the set of data extract files as mentioned via the step 302, at step 402, a script may be generated. The script may be configured to scan the simulation logs or log files of the current simulation run to create the set of data extract files. It should be noted that, the script may correspond to a sequence of instructions that are carried out to automate execution of a task. Once the script is generated, at step 404, the generated script may be executed on the simulation logs or log files based on a user input.

Examples of the simulation logs or log files may include, but are not limited to, a simulation transcript log, a driver log, a monitor log, a checker log, and a scoreboard log. Further, examples of the set of data extract files may include, but is not limited to, Device Under Test (DUT) or Register Transfer Level (RTL) and Testbench (TB) configurations, a list of checker checks, a list of scoreboard checks, a summary report of checks, a start simulation time, an end simulation time, an input stimulus window, a list of error messages, and a list of warning messages. By way of example, the user input may include creation of the set of data extract files corresponding to the driver log, the monitor log, and the checker log from the simulation logs or log files available for the current simulation run. In an embodiment, the set of data extract files created based on the user input may have salient data points (or simulation data) associated with the driver log, the monitor log, and the checker log.

Referring now to FIG. 5, a flowchart of a method 500 for generating a unique signature for a data extract file is illustrated, in accordance with an embodiment. With reference to FIG. 3, in order to generate the unique signature for a data extract file from the set of data extract files as mentioned via step 304, at step 502, at least two hash codes may be generated for the data extract file. In order to generate each of the at least two hash codes, at step 504, a unique hashing algorithm may be executed on the data extract file to generate a hash code from the at least two hash codes. It should be noted that, the unique hashing algorithm used for generating each of the at least two hash codes for the data extract file may be different.

By way of an example, with reference to FIG. 2, in order to generate the unique signature 2 for the sim data extract file 2, a hash code 2 and a hash code 2′ may be generated. The hash code 2 may be generated by executing a unique hashing algorithm, i.e., the hash algorithm 1 (e.g., the sha512sum) on the sim data extract file 2. Similarly, the hash code 2′ may be generated by executing a unique hashing algorithm, i.e., the hash algorithm 2 (e.g., the sha256sum) on the sim data extract file 2. As will be appreciated, the hash algorithm 1 and the hash algorithm 2 may be used for generating the at least two hash codes for each of the set of data extract files.

Once the at least two hash codes are generated for the data extract file, at step 506, the at least two hash codes may be concatenated to generate the unique signature for the corresponding data extract file. In continuation to the previous example, when the hash code 2 and the hash code 2′ are generated for the sim data extract file 2, then the hash code 2 and the hash code 2′ may be concatenated to generate the unique signature 2 for the sim data extract file 2. As will be appreciated, in a similar manner, the unique signature may be generated for each of the set of data extract files.

Referring now to FIG. 6, a flowchart of a method 600 for creating a signature log file is illustrated, in accordance with an embodiment. With reference to FIG. 3, in order to create the signatures log file as mentioned via the step 306, at the step 602, the unique signature generated for each of the set of data extract files may be sequentially stored in the signature log file. In an embodiment, the sequence for storing the unique signature corresponding to each of the set of data extract files may correspond to the sequence of creation of each of the set of data extract files.

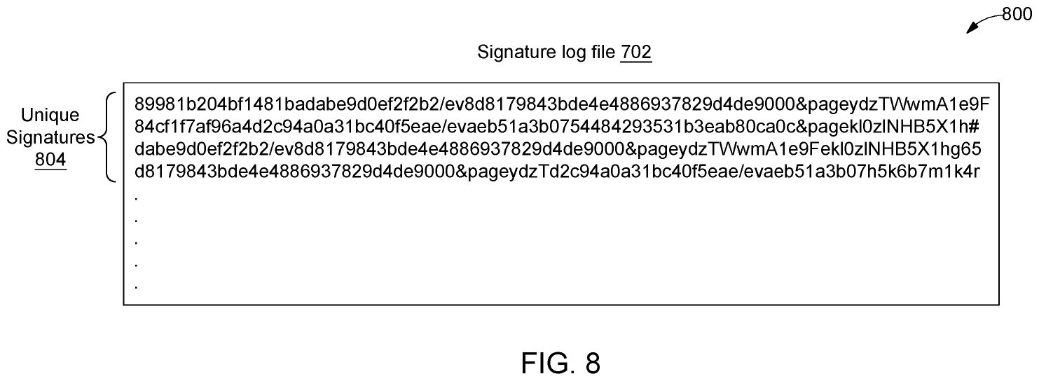

By way of an example, with reference to FIG. 2, when the sequence for creation of the set of data extract files, i.e., the sim data extract file 1, the sim data extract file 2, the sim data extract file 3, the sim data extract file 4, up to the sim data extract file ‘n’ may correspond to creation of the sim data extract file 1 followed by creation of the sim data extract file 2. The creation of the sim data extract file 2 followed by the sim data extract file 3 and so on up to the sim data extract file ‘n’. Then, the sequence for storing the unique signature corresponding to each of the set of data extract files in the signature log file 208 may correspond to the unique signature 1 followed by the unique signature 2 and so on, up to the unique signature ‘n’, respectively. An exemplary representation of a signature log file 802 (same as the signature log file 208) is depicted via a snapshot 800 of FIG. 8. As depicted via the snapshot 800, the signature log file 802 may include unique signatures 804 generated for a set of four data extract files. It should be noted that, each of the unique signatures 804 may be sequentially stored in the signature log file 802.

Referring now to FIG. 7, a flowchart of a method 700 for creating a signature log file is illustrated, in accordance with an embodiment. With reference to FIG. 3, in order to create the signatures log file as mentioned via the step 306, at step 702, once the set of data extract files are created, a token may be assigned to each of the set of data extract files. In an embodiment, the token may correspond to a unique identifier (ID) assigned to each of the set of data extract files. Further, once the token is assigned to each of the set of data extract files, the unique signature may be generated for each of the set of data extract files. The method of generating the unique signature has been already explained in detail in reference to FIG. 5. Once the unique signature for each of the set of data extract files are generated, then at step 704, the generated unique signature may be stored in the signature log file (same as the signature log file 208). In an embodiment, the unique signature generated for each of the set of data extract files may be stored in association with the token assigned to each of the set of data extract files.

Referring now to FIG. 9, a flowchart of a method 900 for generating a consolidated signature for a signature log file is illustrated, in accordance with an embodiment. With reference to FIG. 3, in order to generate the consolidated signature for the signature log file as mentioned via the step 308, at step 902, at least two hash codes may be generated for the signature log file. In order to generate each of the at least two hash codes, at step 904, the unique hashing algorithm may be executed on the simulation log file to generate a hash code from the at least two hash codes. It should be noted that, the unique hashing algorithm used for generating each of the at least two hash codes for the signature log file may be different from each other. However, the unique hashing algorithm used for generating each of the at least two hash codes for the signature log file may be same as the unique hashing algorithm used for generating each of the at least two hash codes for each of the set of data extract files.

By way of an example, with reference to FIG. 2, in order to generate the consolidated signature for the signature log file 208, the hash code X and the hash code X′ may be generated for the signature log file 208. The hash code X may be generated by executing the unique hashing algorithm, i.e., the hash algorithm 1 (e.g., the sha512sum) on the signature log file 208. Similarly, the hash code X′ may be generated by executing the unique hashing algorithm, i.e., the hash algorithm 2 (e.g., the sha256sum) on the signature log file 208.

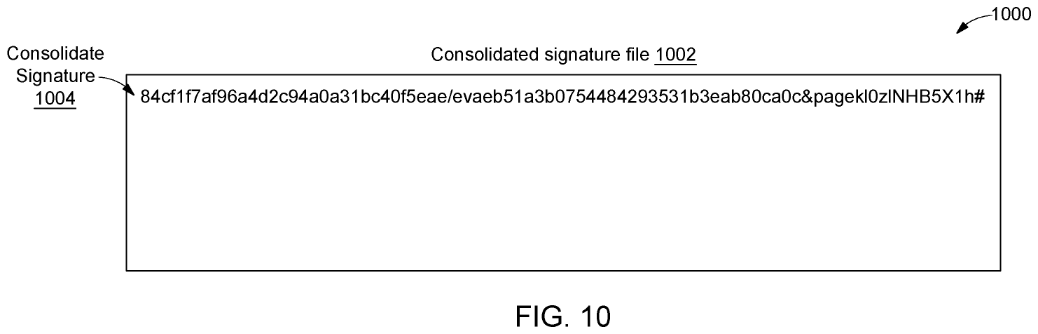

Once the at least two hash codes are generated for the signature log file, then at step 906, the at least two hash codes generated for the signature log file may be concatenated to generate the consolidated signature for the signature log file. In continuation to the previous example, when the hash code X and the hash code X′ are generated for the signature log file 208, then the hash code X and the hash code X′ may be concatenated to generate the consolidated signature for the signature log file 208. Further, the generated consolidated signature may be stored in the consolidated signature file 210. An exemplary representation of a consolidated signature 1004 stored in a consolidated signature file 1002 (same as the consolidated signature file 210) is depicted via a snapshot 1000 of FIG. 10.

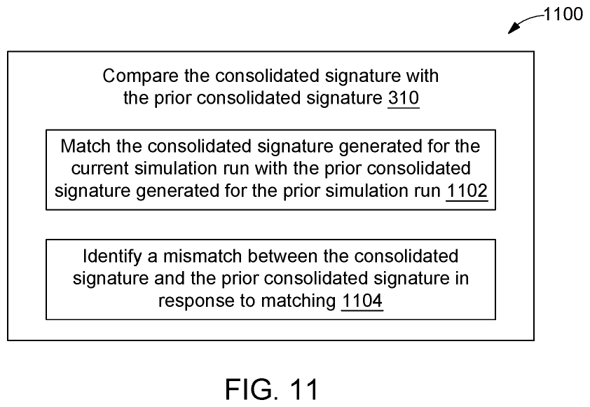

Referring to FIG. 11, a flowchart of a method 1100 for comparing a consolidated signature with a prior consolidated signature is illustrated, in accordance with an embodiment. With reference to FIG. 3, in order to compare the consolidated signature with the prior consolidated signature as mentioned via the step 310, at step 1102, the consolidated signature generated for the current simulation run may be matched with the prior consolidated signature generated for the prior simulation run. Further, at step 1104, a mismatch may be identified between the consolidated signature of the current simulation run and the prior consolidated signature in response to the matching. In one embodiment, when the mismatch is not identified between the consolidated signature and the prior consolidated signature, the current simulation run may be determined to be identical to the prior simulation run. In another embodiment, when the mismatch is identified between the consolidated signature and the prior consolidated signature, then the current simulation run may be determined to deviate from the prior simulation run.

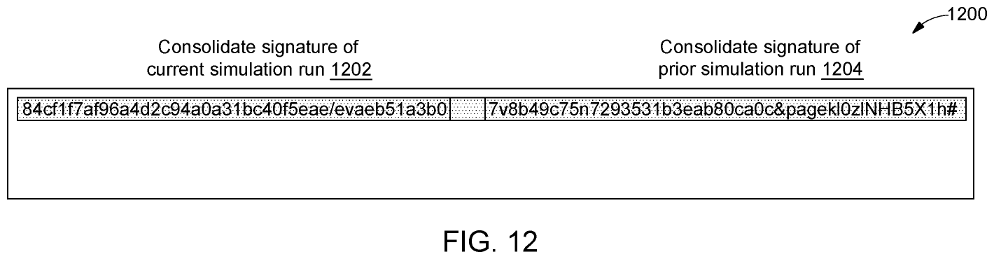

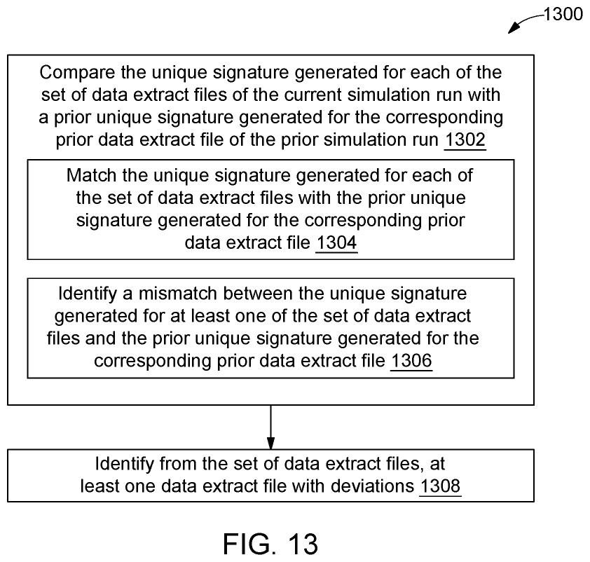

Upon identifying the deviation, the unique signature generated for each of the set of the data extract files may be compared with the unique signature generated for the corresponding prior data extract file of the prior simulation run to identify the at least one data extract file. A method of comparing the unique signature generated for each of the set of the data extract files with unique signature generated for the corresponding prior data extract file of the prior simulation run is explained in detail in conjunction with FIG. 13. An exemplary representation of comparison of a consolidated signature generated for a current simulation run 1202 with a prior consolidated signature generated for a prior simulation run 1204 is depicted via a snapshot 1200 of FIG. 12.

Referring now to FIG. 13, a flowchart of a method 1300 for comparing a unique signature generated for each of a set of data extract files with a prior unique signature generated for a corresponding prior data extract file of a prior simulation run is illustrated, in accordance with an embodiment. With reference to FIG. 11, upon identifying the mismatch between the consolidated signature and the prior consolidated signature, at step 1302, the unique signature generated for each of the set of data extract files of the current simulation run may be compared with the prior unique signature generated for the corresponding prior data extract file of the prior simulation run. In order to compare the unique signature, at step 1304, the unique signature generated for each of the set of data extract files may be matched with the prior unique signature generated for the corresponding prior data extract file. Further, based on the matching, at step 1306, a mismatch may be identified between the unique signature generated for at least one of the set of data extract files and the prior unique signature generated for the corresponding prior data extract file.

By way of an example, with reference to FIG. 2, upon identifying the mismatch between the consolidated signature and the prior consolidated signature, the unique signature 1 generated for the sim data extract file 1 may be matched with a prior unique signature 1 of a prior sim data extract file 1 of the prior simulation run. Based on the matching, a check may be performed to identify a mismatch between the unique signature 1 and the prior unique signature 1. In one case, when no mismatch is identified between the unique signature 1 and the prior unique signature 1, the unique signature 2 may be compared with a prior unique signature 2 to identify a mismatch. This process of identifying the mismatch between the unique signature of each of the set of data extract files and the prior unique signature generated for the corresponding prior data extract file may continue until the at least one data extract file is identified with deviation from the set of data extract files of the current simulation run as mentioned via the step 1308. Once the at least one data extract file with deviation is identified, then the salient data points associated with the at least one data extract file depicting the deviation may be reported to the user.

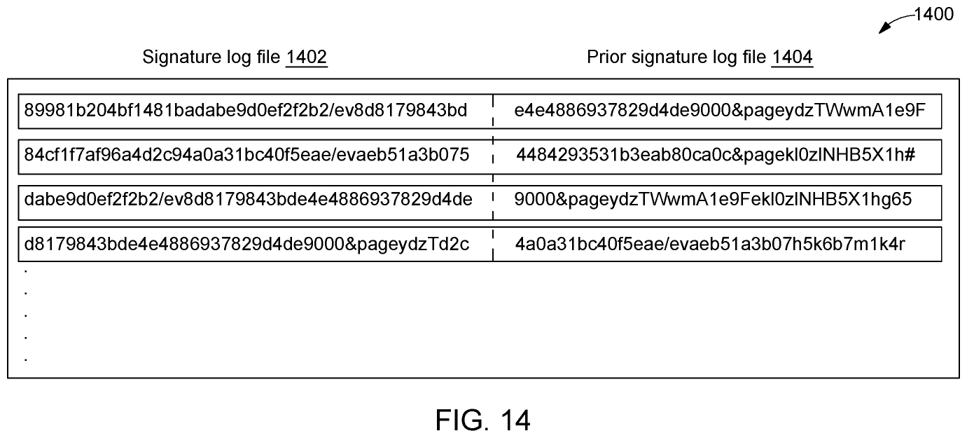

An exemplary representation of comparison of the unique signature generated for each the set of data extract files with the prior unique signature generated for the corresponding prior data extract file of the prior simulation run is depicted via a snapshot 1400 of FIG. 14. In the snapshot 1400, a comparison of the unique signature generated for each of the set of data extract files present within a signature log file (1402) with the prior unique signature generated for the corresponding prior data extract file present within a prior signature log file (1404) is depicted.

Referring now to FIG. 15, a flowchart of a method for identifying at least one data extract file with deviations from a set of data extract files is illustrated, in accordance with an embodiment. With reference to FIG. 2, the method 1500 may be performed by the simulation data analyzer 206. Once the consolidated signature is generated for the signature log file of the current simulation run, then at step 1502, the consolidated signature of the current simulation run may be compared with the prior consolidated signature of the prior simulation run.

In one embodiment, the prior simulation run may correspond to a simulation run executed without any issue, i.e., the golden simulation run. In another embodiment, the prior simulation run may correspond to a simulation run that executed with at least one issue. Further, based on the comparison, at step 1504, a check may be performed to identify whether the consolidated signature deviates from the prior consolidated signature. In other words, a mismatch may be identified between the consolidated signature and the prior consolidated signature.

By way of an example, consider a scenario where the prior simulation run may correspond to the golden simulation run. In this scenario, based on the check performed, in one embodiment, when no mismatch is identified between the consolidated signature and the prior consolidated signature, then the current simulation run is determined to be the passing simulation run. Upon determining the current simulation run as the passing simulation run, at step 1506, the method 1500 may stop. In other words, upon not identifying any mismatch between the consolidated signature and the prior consolidated signature, the simulation data analyzer 206 may conclude the current simulation to be error free. In another embodiment, based on the check performed, when the mismatch is identified between the consolidated signature and the prior consolidated signature, then the current simulation run is determined to be the failing simulation run.

Upon identifying the mismatch between the consolidated signature and the prior consolidated signature, at step 1508, the unique signature generated for a data extract file from the set of data extract files of the current simulation run may be compared with the prior unique signature generated for the corresponding prior data extract file of the prior simulation run. Based on the comparison of the unique signature of the data extract file with the prior unique signature of the corresponding prior data extract file, at step 1510, a check may be performed to identify whether the unique signature deviates from the prior unique signature. In other words, the check may be performed to identify a mismatch between the unique signature and the prior unique signature.

Further, in one embodiment, based on the check performed, when no mismatch is identified between the unique signature of the data extract file and the prior unique signature of the corresponding prior data extract file, then the step 1508 may be re-iterated. This is done to identify at least one data extract file with deviation from the corresponding prior data extract file. In other words, the step 1508 may be re-executed until the at least one data extract file with deviation is identified from the set of data extract files associated with the current simulation run. In another embodiment, based on the check performed, when the mismatch is identified between the unique signature of the data extract file and the prior unique signature of the corresponding prior data extract file, then at step 1512, the data extract file may be identified as the at least one data extract file with deviations. Once the at least one data extract file with deviations is identified, then the salient data points associated with the data extract file may be provided as the result to the user. In an embodiment, the salient data points may denote the simulation data of the data extract file which differs from simulation data of the corresponding prior simulation data extract file.

Various embodiments provide method and system for analyzing simulation data. The disclosed method and system may create a set of data extract files from simulation logs associated with a current simulation run. The disclosed method and system may generate a unique signature for each of the set of data extract files. Further, the disclosed method and system may create a signature log file including the unique signature generated for each of the set of data extract files. In addition, the disclosed method and system may generate a consolidated signature for the signature log file. Further, the disclosed method and system may compare the consolidated signature with a prior consolidated signature generated for a prior simulation run. The prior simulation run may have executed without issues. Thereafter, the disclosed method and system may determine whether the current simulation run deviates from the prior simulation run, based on the comparison between the consolidated signature and the prior consolidated signature.

The disclosed method and system may provide some advantages like, the disclosed method and the system may be methodology independent and hence may be used across any of an existing industry standard verification methodology. Further, the disclosed method and the system may enable users to quickly analyse simulation results to identify a reason for simulation run failure in a reduced time span with less manual effort. This is done by comparing simulation data of current simulation run with the corresponding simulation data of a prior simulation run in a relatively shorter duration. In addition, the disclosed method and the system may store the simulation data corresponding to multiple simulations for future references using minimum device storage memory. Moreover, the disclosed method and the system may enable new team members to quickly understand an existing simulation environment and perform simulation failure or result analysis.

It will be appreciated that, for clarity purposes, the above description has described embodiments of the invention with reference to different functional units and processors. However, it will be apparent that any suitable distribution of functionality between different functional units, processors or domains may be used without detracting from the invention. For example, functionality illustrated to be performed by separate processors or controllers may be performed by the same processor or controller. Hence, references to specific functional units are only to be seen as references to suitable means for providing the described functionality, rather than indicative of a strict logical or physical structure or organization.

Although the present invention has been described in connection with some embodiments, it is not intended to be limited to the specific form set forth herein. Rather, the scope of the present invention is limited only by the claims. Additionally, although a feature may appear to be described in connection with particular embodiments, one skilled in the art would recognize that various features of the described embodiments may be combined in accordance with the invention.

Furthermore, although individually listed, a plurality of means, elements or process steps may be implemented by, for example, a single unit or processor. Additionally, although individual features may be included in different claims, these may possibly be advantageously combined, and the inclusion in different claims does not imply that a combination of features is not feasible and/or advantageous. Also, the inclusion of a feature in one category of claims does not imply a limitation to this category, but rather the feature may be equally applicable to other claim categories, as appropriate.

What is claimed is:

1. A method for analysing simulation data, the method comprising:
creating a set of data extract files from simulation logs associated with a current simulation run;
generating a unique signature for each of the set of data extract files;
creating a signature log file comprising the unique signature generated for each of the set of data extract files;
generating a consolidated signature for the signature log file;
comparing the consolidated signature with a prior consolidated signature generated for a prior simulation run; and
determining whether the current simulation run deviates from the prior simulation run, based on the comparison between the consolidated signature and the prior consolidated signature.

2. The method of claim 1, further comprising:
generating a script configured to scan the simulation logs of the current simulation run to create the set of data extract files.

3. The method claim 2, wherein creating the set of data extract files comprises executing the script on the simulation logs based on a user input.

4. The method of claim 1, wherein generating the unique signature for a data extract file from the set of data extract files comprises:
generating at least two hash codes for the data extract file, wherein generating a hash code from the at least two hash codes comprises:
executing a unique hashing algorithm on the data extract file to generate the hash code from the at least two hash codes; and
concatenating the at least two hash codes to generate the unique signature for the data extract file.

5. The method of claim of 1, wherein generating the consolidated signature for the signature log file comprises:
generating at least two hash codes for the signature log file, wherein generating a hash code from the at least two hash codes comprises:
executing the unique hashing algorithm on the signature log file to generate the hash code from the at least two hash codes; and
concatenating the at least two hash codes to generate the consolidated signature for the signature log file.

6. The method of claim 1, wherein creating the signature log file comprises sequentially storing the unique signature generated for each of the set of data extract files, wherein the unique signature generated for each of the set of data extract files is sequentially stored based on a sequence of creation of each of the set of data extract files.

7. The method of claim 1, wherein creating the signature log file comprises:
assigning a token to each of the set of data extract files; and
storing the unique signature generated for each of the set of data extract files in association with the assigned token.

8. The method of claim 1, wherein comparing the consolidated signature with the prior consolidated signature comprises:
matching the consolidated signature generated for the current simulation run with the prior consolidated signature generated for the prior simulation run; and
identifying a mismatch between the consolidated signature and the prior consolidated signature in response to matching.

9. The method of claim 8, further comprising:
comparing the unique signature generated for each of the set of data extract files of the current simulation run with a prior unique signature generated for the corresponding prior data extract file of the prior simulation run, upon identifying the mismatch between the consolidated signature and the prior consolidated signature, wherein the comparing comprises:
matching the unique signature generated for each of the set of data extract files with the prior unique signature generated for the corresponding prior data extract file; and
identifying a mismatch between the unique signature generated for at least one of the set of data extract files and the prior unique signature generated for the corresponding prior data extract file.

10. The method of claim 9, further comprising:
identifying from the set of data extract files, at least one data extract file with deviations based on the mismatch identified between the unique signature of the at least one data extract file and the prior unique signature of the corresponding prior data extract file.

11. A system for analysing simulation data, the system comprising:
a processor; and
a memory coupled to the processor, wherein the memory stores processor-executable instructions, which, on execution, causes the processor to:
create a set of data extract files from simulation logs associated with a current simulation run;
generate a unique signature for each of the set of data extract files;
create a signature log file comprising the unique signature generated for each of the set of data extract files;
generate a consolidated signature for the signature log file;
compare the consolidated signature with a prior consolidated signature generated for a prior simulation run; and
determine whether the current simulation run deviates from the prior simulation run, based on the comparison between the consolidated signature and the prior consolidated signature.

12. The system of claim 11, wherein the processor-executable instructions further cause the processor to:
generate a script configured to scan the simulation logs of the current simulation run to create the set of data extract files.

13. The system of claim 12, wherein, to create the set of data extract files, the processor-executable instructions further cause the processor to execute the script on the simulation logs based on a user input.

14. The system of claim 11, wherein, to generate the unique signature for a data extract file from the set of data extract files, the processor executable instructions further cause the processor to:
generate at least two hash codes for the data extract file, wherein generating a hash code from the at least two hash codes comprises:
executing a unique hashing algorithm on the data extract file to generate the hash code from the at least two hash codes; and
concatenate the at least two hash codes to generate the unique signature for the data extract file.

15. The system of claim 11, wherein, to generate the consolidated signature for the signature log file, the processor executable instructions further cause the processor to:
generate at least two hash codes for the signature log file, wherein generating a hash code from the at least two hash codes comprises:
executing the unique hashing algorithm on the signature log file to generate the hash code from the at least two hash codes; and
concatenate the at least two hash codes to generate the consolidated signature for the signature log file.

16. The system of claim 11, wherein, to create the signature log file, the processor executable instructions further cause the processor to sequentially store the unique signature generated for each of the set of data extract files, wherein the unique signature generated for each of the set of data extract files is sequentially stored based on a sequence of creation of each of the set of data extract files.

17. The system of claim 11, wherein, to create the signature log file, the processor executable instructions further cause the processor to:
assign a token to each of the set of data extract files; and
store the unique signature generated for each of the set of data extract files in association with the assigned token.

18. The system of claim 11, wherein, to compare the consolidated signature with the prior consolidated signature, the processor executable instructions further cause the processor to:
match the consolidated signature generated for the current simulation run with the prior consolidated signature generated for the prior simulation run; and
identify a mismatch between the consolidated signature and the prior consolidated signature in response to matching.

19. The system of claim 18, the processor executable instructions further cause the processor to:
compare the unique signature generated for each of the set of data extract files of the current simulation run with a prior unique signature generated for the corresponding prior data extract file of the prior simulation run, upon identifying the mismatch between the consolidated signature and the prior consolidated signature, wherein the comparing comprises:
match the unique signature generated for each of the set of data extract files with the prior unique signature generated for the corresponding prior data extract file; and
identify a mismatch between the unique signature generated for at least one of the set of data extract files and the prior unique signature generated for the corresponding prior data extract file.

20. The system of claim 19, the processor executable instructions further cause the processor to:
identify from the set of data extract files, at least one data extract file with deviations based on the mismatch identified between the unique signature of the at least one data extract file and the prior unique signature of the corresponding prior data extract file.

21. A non-transitory computer-readable medium storing computer-executable instructions for analysing simulation data, the stored instructions, when executed by a processor, cause the processor to perform operations comprises:
creating a set of data extract files from simulation logs associated with a current simulation run;
generating a unique signature for each of the set of data extract files;
creating a signature log file comprising the unique signature generated for each of the set of data extract files;
generating a consolidated signature for the signature log file;
comparing the consolidated signature with a prior consolidated signature generated for a prior simulation run; and
determining whether the current simulation run deviates from the prior simulation run, based on the comparison between the consolidated signature and the prior consolidated signature.
